(19) United States
(12) Patent Application Publication
(10) Pub. No.: US 2026/0372098 A1
(43) Pub. Date: Nov. 19, 2026

(54) INSULATING BUFFERS TO MITIGATE CRACKING IN MEMORY DEVICE

(71) Applicant: MICRON TECHNOLOGY, INC., Boise, ID (US)

(72) Inventor: Martina Damayanti, Singapore (SG)

(21) Appl. No.: 19/210,080

(22) Filed: May 16, 2025

(51) Int. Cl. H10W 42/00

(52) U.S. Cl. CPC H10W 42/121

(57) ABSTRACT

A memory array includes a stack of layers including alternating layers of a dielectric material and a conductive material. The memory array further includes a plurality of supporting pillars extending through the stack of layers within a first region of at least one layer of the stack of layers. The memory array further includes a plurality of contacts extending through the stack of layers within a second region of the at least one layer of the stack of layers. The memory array further includes a plurality of insulating buffers disposed at a transition region of the at least one layer of the stack of layers. The transition region is located between the first region and the second region. Each of the plurality of insulating buffers at least partially surrounds an associated contact of the plurality of contacts.

### TECHNICAL FIELD

Embodiments of the disclosure relate generally to memory sub-systems, and more specifically, relate to insulating buffers to mitigate cracking in a memory device.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A and 1B are schematic top-down representations of insulating buffers to mitigate cracking in a memory device in accordance with some embodiments of the present disclosure.

FIGS. 2A and 2B are schematic representations for a first operation of a method of manufacturing a memory device in accordance with some embodiments of the present disclosure.

FIGS. 3A and 3B are schematic representations for a second operation of a method of manufacturing a memory device in accordance with some embodiments of the present disclosure.

FIGS. 4A and 4B are schematic representations for a third operation of a method of manufacturing a memory device in accordance with some embodiments of the present disclosure.

FIG. 5 is a flow diagram of an example method of manufacturing a memory array in accordance with some embodiments of the present disclosure.

FIG. 6A illustrates an example computing system that includes a memory sub-system in accordance with some embodiments of the present disclosure.

FIG. 6B is a block diagram of a memory device in communication with a memory sub-system controller of a memory sub-system, according to an embodiment.

### DETAILED DESCRIPTION

Aspects of the present disclosure are directed to insulating buffers in an electronic device, such as a memory device (e.g., a storage device, a memory array, etc.), to reduce or eliminate cracking, and method(s) of forming thereof. Storage devices such as solid-state drives (SSDs) may include 3-dimensional (3D) NAND flash memory technology. Traditional NAND flash memory stores data in a 2-dimensional (2D) structure, where memory cells are laid out on a single layer of dielectric material. 3-dimensional (3D) NAND instead stacks memory cells vertically in multiple layers (hence the “3D” designation). Such vertical stacking allows for increased storage densities and greater storage capacity in a comparatively smaller physical footprint when compared to planar NAND. A key advantage of 3D NAND is its ability to continue increasing storage capacities while maintaining or even improving performance and reliability. 3D NAND technology has enabled the development of SSDs with larger capacities, faster speeds, and lower costs per unit of storage.

A 3D NAND device includes multiple memory cells stacked vertically in multiple tiers, such that an inner tier of the stack is adjacent to two neighboring tiers, while an outer tier of the stack is adjacent to one neighboring tier. In order to achieve higher storage capacities and/or improve performance of the device, the number of tiers within a single memory device may be increased, thus allowing for higher-capacity storage devices. However, the increase in the number of tiers also increases the overall height of the 3D NAND structure. To limit the height of the 3D NAND structure, the thickness of each tier can be decreased.

In some embodiments, in a 3D NAND structure, supporting pillars extend vertically through at least some of the tiers. The supporting pillars may provide structure for the tiers, such as during manufacturing so the tiers don't collapse on themselves. The supporting pillars may be disposed in a memory array region of the 3D NAND structure. In some embodiments, in a 3D NAND structure, contacts extend vertically through at least some of the tiers. The contacts may provide electrical connections to layers of the 3D NAND. In some embodiments, at least some of the contacts are “dummy” contacts, meaning the contacts don't provide an electrical connection but instead provide structure for the tiers. In some embodiments, the contacts have a larger cross-section than the supporting pillars. The contacts may be disposed in a staircase region of the 3D NAND structure.

The “staircase region” of a 3D NAND structure may be the part of the vertical stack of layers where the individual memory cells are connected and the structures are gradually stepped or stacked on top of each other. The staircase region may be where a process transitions from one layer of NAND cells to another, characterized by a step-like structure in the physical layout. The staircase region may get its stepped appearance due to the formation of different tiers of the NAND memory cells in a 3D architecture. Formation of the staircase region may involve the formation of channels, access lines, and/or bitlines, etc. that span vertically across multiple layers of memory cells. The channels, access lines, and/or bitlines, etc. may be carefully aligned between layers, creating a steeped or staggered structure (e.g., a staircase structure). The staircase region may play a role in the vertical interconnectivity and/or alignment between the different memory layers in the 3D NAND. The staircase region may allow for interlayer connections while maintaining the overall device performance and manufacturability.

The topology of the memory array region of the 3D NAND may be different from the staircase region of the 3D NAND. The topology difference may be due to different heights of the two different regions and/or due to different materials between the array region and the staircase region. In some embodiments, a transition region is located between the memory array region and the staircase region. Because of the topology differences between the array region and the staircase region (e.g., due to material differences, height differences, etc.), thermal stresses may be induced at the transition region. These induced thermal stresses may cause cracking to occur at the transition region. During subsequent metal deposition processes performed during manufacturing of the 3D NAND, the cracks at the transition region can be inadvertently filled with metal, thus causing electrical shorts. The shorts can be from a wordline to a contact or from one sub-block to another sub-block. In some instances, the electrical shorts can reduce the yield of the memory device and/or require the device to be scrapped.

Aspects of the present disclosure may address the deficiencies described above and other challenges by providing insulating buffers in a memory device to mitigate the cracking that occurs at the transition region between the memory array region and the staircase region of the 3D NAND structure. In some embodiments, the insulating buffers are disposed in the transition region. The insulating buffers may be formed by etching voids at the transition region and then filling the voids with an insulating oxide (e.g., a metalloid oxide, such as silicon oxide). In some embodiments, areas adjacent to contacts located at the edge of the staircase region are etched. Prior to the etching, there may be cracks adjacent to the contacts. In some embodiments, etching the area(s) adjacent to the contacts removes the material that contained the cracks. In some embodiments, voids are formed by the etching. In some embodiments, at least the top layer is etched to form the voids. In some embodiments, multiple layers corresponding to the top deck of the 3D NAND structure are etched to form the voids. Each of the voids may at least partially surround a contact. In some embodiments, the voids are then filled with an insulating oxide to form insulating buffers (e.g., replacing the material that had the cracks). Each of the insulating buffers may at least partially surround a contact. In some embodiments, each of the insulating buffers has a substantially oxbow-shaped cross-section.

In some embodiments, the 3D NAND structure is divided into sub-blocks. A sub-block may include a subset of the supporting pillars and a subset of the contacts. Neighboring sub-blocks may be adjacent to one another and separated by a partition. The partition may be formed by etching a slit (e.g., a trench) between the neighboring sub-blocks and filling the slit with an insulating oxide material (e.g., a metalloid oxide, such as silicon oxide). In some embodiments, at least one of the insulating buffers is formed monolithically with a partition separating one sub-block from another sub-block. For example, a void at least partially surrounding a contact (e.g., a contact adjacent to the transition region) may be formed concurrently with a slit separating a first sub-block from a second sub-block (e.g., the first sub-block neighboring the second sub-block). The void and the slit may be formed during the same etch operation. There may be no boundary between the void and the slit such that the void and the slit are connected. The void and the slit may then be concurrently filled with insulating material (e.g., an insulating oxide material) to monolithically form the insulating buffer and the partition. The void and the slit may be filled during the same deposition operation to form the insulating buffer and the partition. There may be no physical boundary between the insulating buffer and the partition. In some embodiments, the insulating buffer extends from the partition such that the insulating buffer and the partition are a contiguous mass (e.g., a monolithic mass) of insulating material.

Advantages of the present disclosure include, for example, improved 3D NAND structural integrity by the elimination/reduction of cracks at the transition region between the array region and the staircase region. Additionally, by reducing cracks at the transition region, electrical shorts may also be reduced, leading to improved yield and greater functionality of the 3D NAND. Moreover, forming the insulating buffers can be performed concurrent with formation of partitions that separate individual sub-blocks from neighboring sub-blocks, so no additional process may be performed compared to current production. Overall, the present disclosure can improve the performance of a memory sub-system, leading to faster memory operations and/or decreased latency.

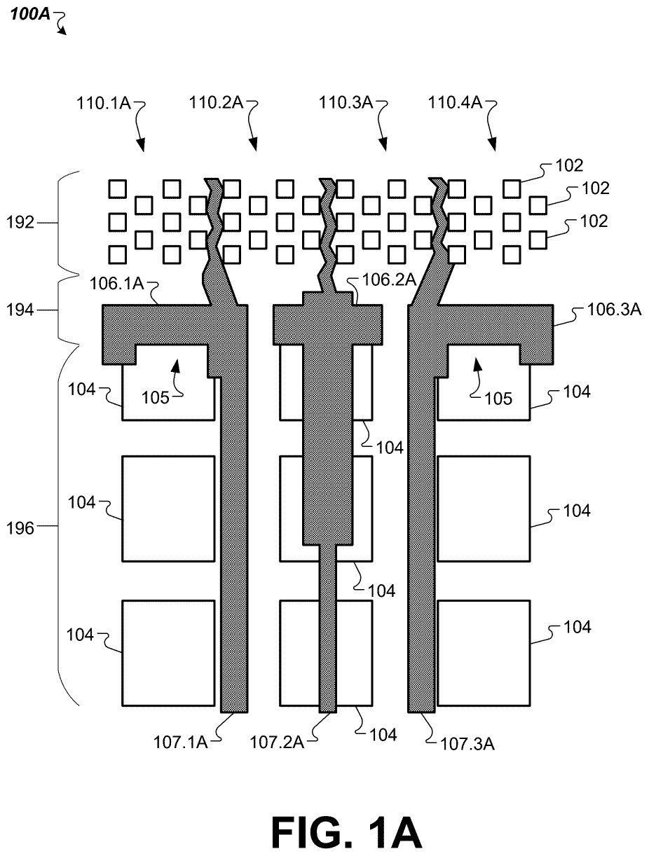

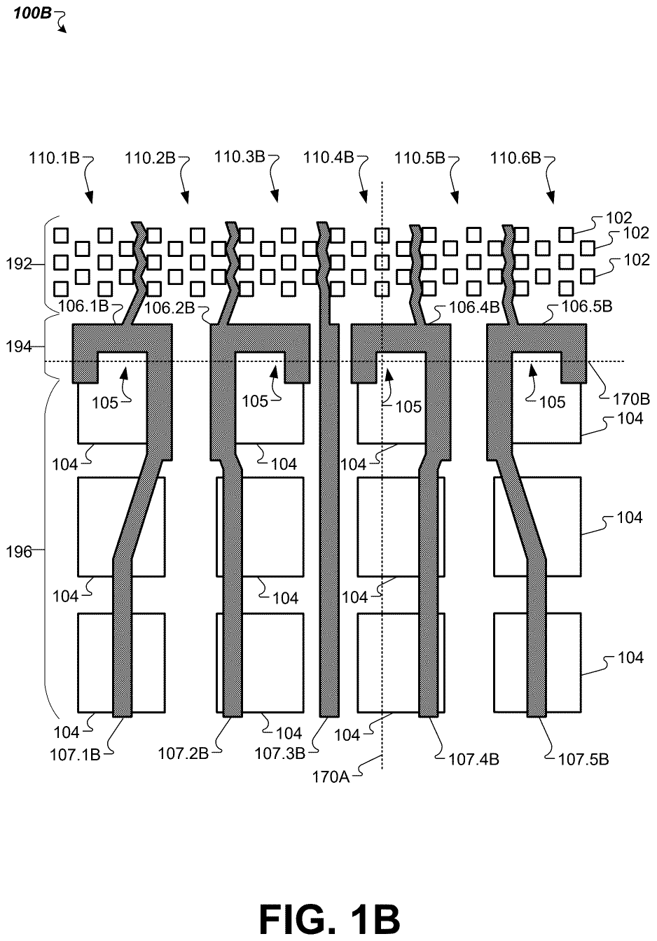

FIGS. 1A and 1B are schematic top-down representations of insulating buffers to mitigate cracking in a memory device in accordance with some embodiments of the present disclosure. Referring to FIG. 1A, a schematic top-down representation 100A of insulating buffers 106 in a memory device is shown. In some embodiments, a memory device includes a supporting pillars 102. The supporting pillars 102 may extend vertically through multiple layers of the memory device. The supporting pillars 102 may be disposed within the memory array region 192 of the memory device. For example, the supporting pillars 102 may extend from a top layer downwards to the memory cells of the memory array. In some embodiments, the supporting pillars 102 provide structural support to the layers of the memory device within the memory array region 192. In some embodiments, the memory device includes contacts 104. The contacts 104 may extend vertically through multiple layers of the memory device. The contacts 104 may be disposed within the staircase region 196 of the memory device. For example, the contacts 104 may extend from a top layer downwards to the staircase of the memory array. In some embodiments, at least one of the contacts 104 is a “dummy” contact, meaning the contact does not provide an electrical connection but instead provides structural support to the layers of the memory device within the staircase region 196. In some embodiments, the contacts 104 are arranged in rows, such as a first row of contacts 104, a second row of contacts 104, a third row of contacts 104, and so on. The first row of contacts 104 may be adjacent to the transition region 194. The first row of contacts 104 may be closer to the transition region 194 than the second row of contacts 104.

The supporting pillars 102 and the contacts 104 may be grouped and/or separated into subsets, such as sub-blocks. Four such sub-blocks may be shown in FIG. 1A. In some embodiments, a first subset of supporting pillars 102 and a first subset of contacts 104 is grouped into a first sub-block 110.1A, a second subset of supporting pillars 102 and a second subset of contacts 104 is grouped into a second sub-block 110.2A, a third subset of supporting pillars 102 and a third subset of contacts 104 is grouped into a third sub-block 110.3A, and a fourth subset of supporting pillars 102 and a fourth subset of contacts 104 is grouped into a fourth sub-block 110.4A. Each of the sub-blocks may be separated from the neighboring sub-block(s) by a partition 107. Each of the partitions 107 may extend through the memory array region 192, the transition region 194, and the staircase region 196. Each of the partitions 107 may be at least one layer deep from the top layer of the stack of layers but can be multiple layers deep in some embodiments. In some embodiments, a first partition 107.1A separates sub-block 110.1A from sub-block 110.2A, a second partition 107.2A separates sub-block 110.2A from sub-block 110.3A, and a third partition 107.3A separates sub-bloc 110.3A from sub-block 110.4A. Each of the partitions may include an insulating oxide-filled slit. In some embodiments, at least one of the partitions splits one or more of the contacts 104. The split one or more contacts 104 may thus be a part of (e.g., belong to, associated with, etc.) two neighboring sub-blocks. In some embodiments, partition 107.2A splits the contacts 104 belonging to sub-block 110.2A and sub-block 110.3A.

Insulating buffers 106 may be disposed at a transition region 194 between the memory array region 192 and the staircase region 196. In some embodiments, each of the insulating buffers 106 at least partially surrounds a contact 104 of the first row of contacts 104 (e.g., the row of contacts 104 adjacent to the transition region 194). The insulating buffers 106 may be disposed at a region where cracking (e.g., thermal cracking) occurs in the 3D NAND structure. The insulating buffers may be formed by etching the region(s) containing cracks to remove the cracks and back-filling the voids with material. In some embodiments, the insulating buffers 106 are composed of an electrically-insulating material, such as an oxide (e.g., a metalloid oxide, such as silicon oxide). The region(s) etched to form the insulating buffers 106 may at least partially include the contacts 104. For example, at least a part of a contact 104 may be etched to form the insulating buffer 106 at least partially surround the contact 104. In some embodiments, the insulating buffers 106 are composed of the same material as the partitions 107. In some embodiments, each of the insulating buffers 106 are monolithic with and/or integral to the connected partition 107. Each of the insulating buffers 106 may be contiguous with the connected partition 107. For example, insulating buffer 106.1A is connected with partition 107.1A, insulating buffer 106.2A is connected with partition 107.2A, and insulating buffer 106.3A is connected with partition 107.3A. There may be no physical boundary between an insulating buffer 106 and the partition 107 to which the insulating buffer 106 is connected. In some embodiments, insulating buffer 106.1A is monolithic with partition 107.1A, insulating buffer 106.2A is monolithic with partition 107.2A, and insulating buffer 106.3A is monolithic with partition 107.3A. Each of the insulating buffers 106 may extend from the partition 107 to which the buffer is connected. For example, insulating buffer 106.1A may extend from partition 107.1A, insulating buffer 106.2A may extend from partition 107.2A, and insulating buffer 106.3A may extend from partition 107.3A. Each of the insulating buffers 106 and partitions 107 may be formed concurrently during the same etch and/or deposition process(es) as described herein below.

At least one of the insulating buffer 106 may have a substantially oxbow-shaped cross-section. For example, and in some embodiments, insulating buffer 106.1A forms an oxbow-shaped cross-section 105 that at least partially surrounds the contact 104. Similarly, insulating buffer 106.3A forms an oxbow-shaped cross-section 105 that at least partially surrounds the contact 104. The oxbow-shaped cross-section 105 may be characterized by its resemblance to the letter “U.” The oxbow-shaped cross-section 105 may have distal ends that curve around the corners of a contact 104.

Referring to FIG. 1B, a schematic top-down representation 100B of insulating buffers 106 in a memory device is shown. Six sub-blocks may be shown in FIG. 1B. For example, sub-block 110.1B is separated from sub-block 110.2B by partition 107.1B, sub-block 110.2B is separated from sub-block 110.3B by partition 107.2B, sub-block 110.3B is separated from sub-block 110.4B by partition 107.3B, sub-block 110.4B is separated from sub-block 110.5B by partition 107.4B, and sub-block 110.5B is separated from sub-block 110.6B by partition 107.5B. At least some of the partitions 107 may be monolithic with (e.g., connected to, associated with, etc.) an insulating buffer 106. For example, insulating buffer 106.1B may be connected with partition 107.1B, insulating buffer 106.2B may be connected with partition 107.2B, insulating buffer 106.4B may be connected with partition 107.4B, and insulating buffer 106.5B may be connected with partition 107.5B. Partition 107.3B may not have a connected insulating buffer. In some embodiments, the insulating buffers 106 extend from the partitions 107. For example, insulating buffer 106.1B may extend from partition 107.1B, insulating buffer 106.2B may extend from partition 107.2B, insulating buffer 106.4B may extend from partition 107.4B, and insulating buffer 106.5B may extend from partition 107.5B. At least some of the insulating buffers 106 may have a substantially oxbow-shaped cross-section. For example, insulating buffers 106.1B, 106.2B, 106.4B, and 106.5B may each have an oxbow-shaped cross-section 105.

In some embodiments, at least one of the partitions 107 splits a contact 104 at the second row of contacts. For example, and in some embodiments, partition 107.1B splits a contact 104 at the second row of contacts. Similarly, partition 107.5B may split a contact 104 at the second row of contacts. By splitting the contact 104 at the second row of contacts 104, cracks and/or shorts typically associated with splitting a contact 104 can be reduced because the splitting of the contact 104 is away from the transition region.

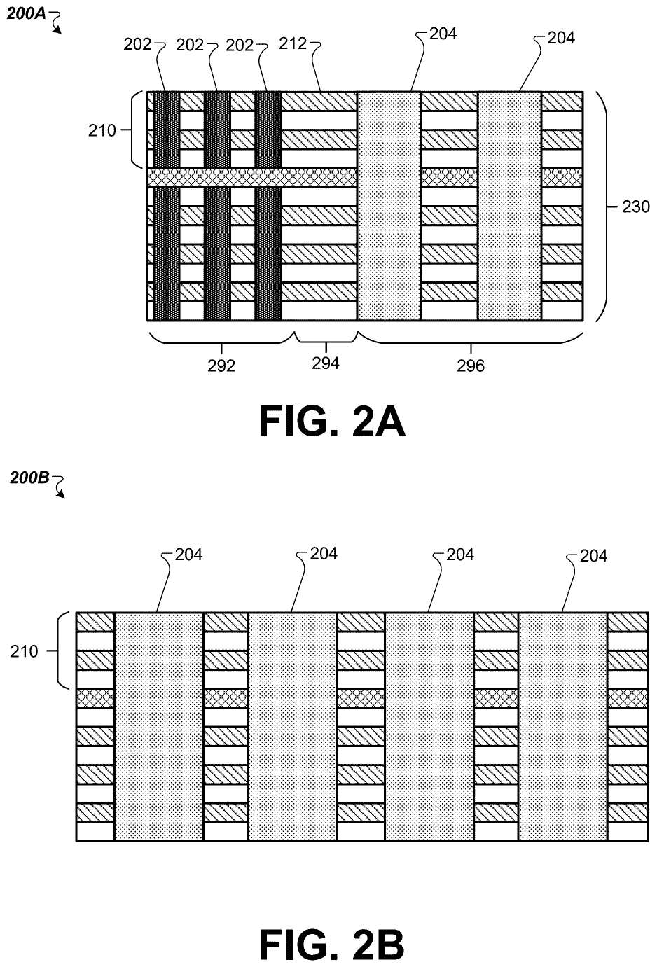

To illustrate the formation of the insulating buffers 106, FIGS. 2A, 2B, 3A, 3B, 4A, and 4B illustrate cross-sectional views of the process operations. FIGS. 2A, 3A, and 4A may illustrate cross-sectional views in a bitline direction, associated with cross-section line 170A shown in FIG. 1B. FIGS. 2B, 3B, and 4B may illustrate cross-sectional views in a wordline direction, associated with cross-section line 170B shown in FIG. 1B. Further details regarding the formation of insulating buffers 106 are described herein below.

FIGS. 2A and 2B are schematic representations for a first operation of a method of manufacturing a memory device in accordance with some embodiments of the present disclosure. FIG. 2A shows a schematic representation 200A on cross-sectional line 170A of FIG. 1B. FIG. 2B shows a schematic representation 200B on cross-sectional line 170B of FIG. 1B.

A memory device may include a stack of layers 230. In some embodiments, the stack of layers 230 includes alternating layers of a dielectric material and a conductive material. In some embodiments, the stack of layers 230 includes alternating layers of a metalloid oxide (e.g., silicon oxide) and a metalloid nitride (e.g., silicon nitride). The stack of layers 230 may be a tier stack, with each tier being formed by multiple layers stacked on one another. In some embodiments, the stack of layers 230 includes a top deck 210. The top deck 210 may include the top several layers of the stack of layers 230. In some embodiments, the top deck 210 includes at least one layer, such as at least a top layer 212 of the stack of layers 230. In some embodiments, the top deck 210 includes at least four layers, such as the top four layers of the stack of layers 230, etc.

Various features may be formed in the stack of layers 230. In some embodiments, supporting pillars 202 are formed in the stack of layers 230 within a memory array region 292. The supporting pillars 202 may provide structural support to the stack of layers 230. In some embodiments, a contacts 204 are formed in the stack of layers 230 within a staircase region 296. A transition region 294 may be located between the memory array region 292 and the staircase region 296.

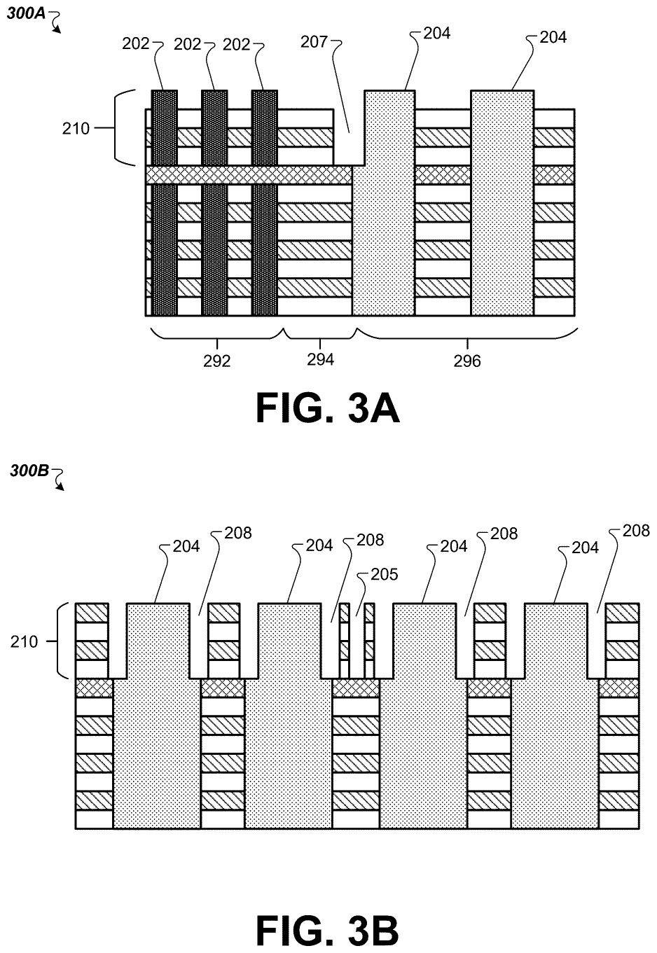

FIGS. 3A and 3B are schematic representations for a second operation of a method of manufacturing a memory device in accordance with some embodiments of the present disclosure. FIG. 3A shows a schematic representation 300A on cross-sectional line 170A of FIG. 1B. FIG. 3B shows a schematic representation 300B on cross-sectional line 170B of FIG. 1B.

At least the top layer 212 (shown in FIGS. 2A and 2B) is etched away. In some embodiments, portions of the top deck are etched to form voids 208. Each of the voids 208 may at least partially surround one of the contacts 204. In some embodiments, each of the voids 208 has a substantially oxbow-shaped cross-section. In some embodiments, a portion of each of the contacts 204 is etched to form the voids 208. Etching to form the voids 208 may remove portions of material having cracks caused by stresses (e.g., thermal stresses) in the stack of layers 230 at the transition region 294. In some embodiments, the voids 208 are formed concurrently with the forming of one or more slits 205. A slit 205 may separate two adjacent sub-blocks from one another. For example, the slit 205 may separate a first subset of supporting pillars 202 and a first subset of contacts 204 from a second subset of supporting pillars 202 and a second subset of contacts 204. The slit 205 may later be filled with material to form a partition that separates the two-adjacent sub-blocks from one another. In some embodiments, the depth of the voids 208 is substantially the same as the depth of the slit 205.

In some embodiments, the voids 208 and/or slit(s) 205 can be formed using a wet etching process or a dry etching process. In some embodiments, a process such as photolithography is used to pattern a mask on top of the stack of layers 230 prior to the etching operation. A wet etching process can involve the use of liquid chemicals or etchants to remove material from the stack of layers 230. A dry etching process can involve using gases or plasmas to remove material from the stack of layers 230. In some embodiments, the same etching process is used to concurrently form the slit(s) 205 and the voids 208.

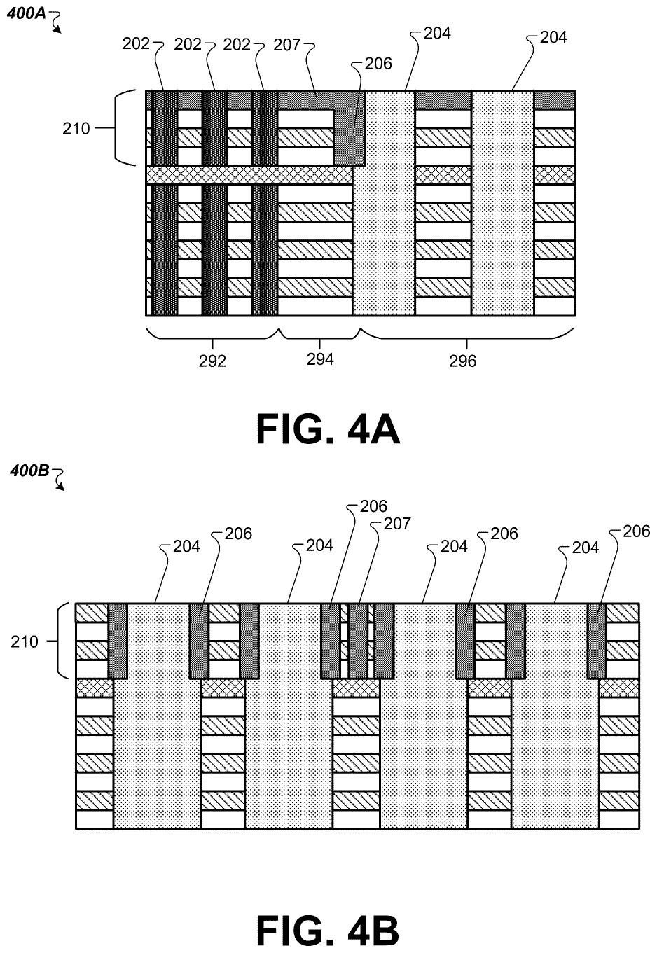

FIGS. 4A and 4B are schematic representations for a third operation of a method of manufacturing a memory device in accordance with some embodiments of the present disclosure. FIG. 4A shows a schematic representation 400A on cross-sectional line 170A of FIG. 1B. FIG. 4B shows a schematic representation 400B on cross-sectional line 170B of FIG. 1B.

The voids 208 and the slit(s) 205 are filled with an electrically-insulating material. The material may be an oxide, such as a metalloid oxide (e.g., silicon oxide). Filling of the voids 208 may form insulating buffers 206. Filling of the slit(s) may form partition(s) 207. Each of the insulating buffers 206 may at least partially surround a contact 204. In some embodiments, the insulating buffers extend vertically through at least a top layer of the stack of layers 230. The insulating buffers extend at least through the layers forming the top deck 210 of the stack of layers 230. In some embodiments, each of the insulating buffers 206 is connected with a respective partition 207. The insulating buffers 206 may be monolithic (e.g., contiguous) with the connected partition 207.

The electrically-insulating material may be deposited using chemical vapor deposition (CVD) techniques, atomic layer deposition (ALD) techniques, sputtering techniques, etc. After the processes described herein above are performed, the transition region 294 may be substantially devoid of cracks in some embodiments.

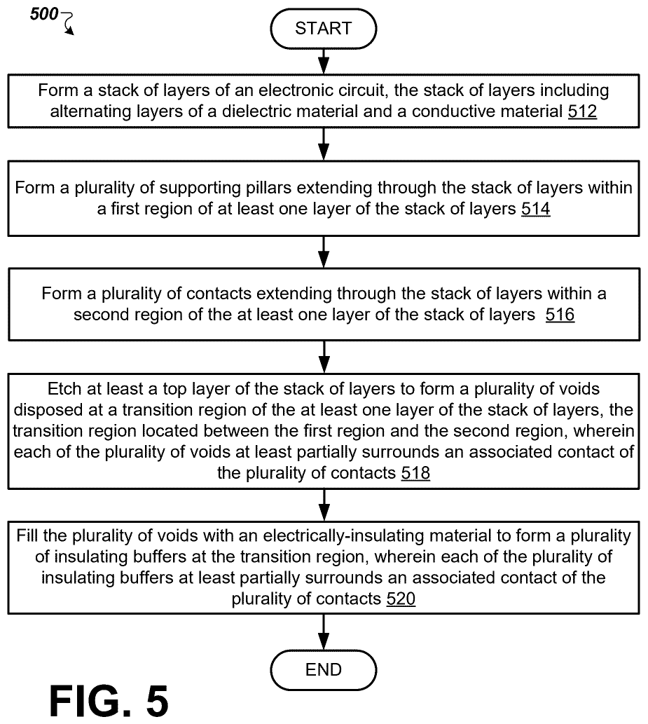

FIG. 5 is a flow diagram of an example method 500 of manufacturing a memory array in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 512, a stack of layers of an electronic circuit is formed. In some embodiments, the stack of layers includes alternating layers of a dielectric material and a conductive material. In some embodiments, the stack of layers includes alternating layers of a metalloid oxide (e.g., silicon oxide) and a metalloid nitride (e.g., silicon nitride). In some embodiments, the stack of layers includes a top deck. The top deck may include the top several layers of the stack of layers. In some embodiments, the top deck includes at least one layer, such as at least a top layer of the stack of layers.

At block 514, a plurality of supporting pillars are formed extending through the stack of layers within a first region of at least one layer of the stack of layers. In some embodiments, supporting pillars are formed in a memory array region of the stack of layers. The supporting pillars may extend vertically through at least one layer in the memory array region. The supporting pillars may be formed by performing one or more etch operations to open holes in the stack of layers (e.g., in the memory array region) and subsequently performing one or more deposition operations to fill the open holes, thus forming the plurality of supporting pillars.

At block 516, a plurality of contacts are formed extending through the stack of layers within a second region of at least one layer of the stack of layers. In some embodiments, contacts are formed in a staircase region of the stack of layers. The contacts may extend vertically through at least one layer in the staircase region. The contacts may be formed by performing one or more etch operations to open holes in the stack of layers (e.g., in the staircase region) and subsequently performing one or more deposition operations to fill the open holes, thus forming the plurality of contacts. In some embodiments, at least one of the contacts is a “dummy” contact that does not provide electrical connectivity.

At block 518, at least a top layer of the stack of layers is etched to form a plurality of voids disposed at a transition region of the at least one layer of the stack of layers. The transition region may be located between the first region (e.g., the memory array region) and the second region (e.g., the staircase region). In some embodiments, each of the plurality of voids at least partially surrounds an associated contact of the plurality of contacts. In some embodiments, at least one of the plurality of voids has a substantially oxbow-shaped cross-section. In some embodiments, the plurality of voids may be formed by performance of an etch operation, such as a wet etch operation or a dry etch operation. Etching at least the top layer of the stack of layers to form the plurality of voids may be performed concurrent with etching at least the top layer of the stack of layers to form a slit. The slit may be for separating a first subset of the plurality of supporting pillars and a first subset of the plurality of contacts (e.g., a first sub-block) from a second subset of the plurality of supporting pillars and a second subset of the plurality of contacts (e.g., a second sub-block). In some embodiments, the plurality of voids are formed using the same etch operation used to form one or more slits in the stack of layers. In some embodiments, by forming the plurality of voids at the transition region, cracking in the stack of layers may be removed.

At block 520, the plurality of voids are filled with an electrically-insulating material to form a plurality of insulating buffers at the transition region. In some embodiments, each of the plurality of insulating buffers at least partially surrounds an associated contact of the plurality of contacts. In some embodiments, at least one of the insulating buffers has a substantially oxbow-shaped cross-section. In some embodiments, the plurality of insulating buffers may be formed by performance of a deposition operation, such as CVD, ALD, or sputter, etc. Deposition of the electrically-insulating material into the plurality of voids to form the plurality of insulating buffers may be performed concurrent with deposition of electrically-insulating material into the slit(s) to form one or more partitions. The one or more partitions may be for separating the first subset of the plurality of supporting pillars and the first subset of the plurality of contacts (e.g., the first sub-block) from the second subset of the plurality of supporting pillars and the second subset of the plurality of contacts (e.g., the second sub-block). The insulating buffers may extend from the one or more partitions. In some embodiments, the plurality of insulating buffers are formed using the same deposition operation used to form one or more partitions in the stack of layers.

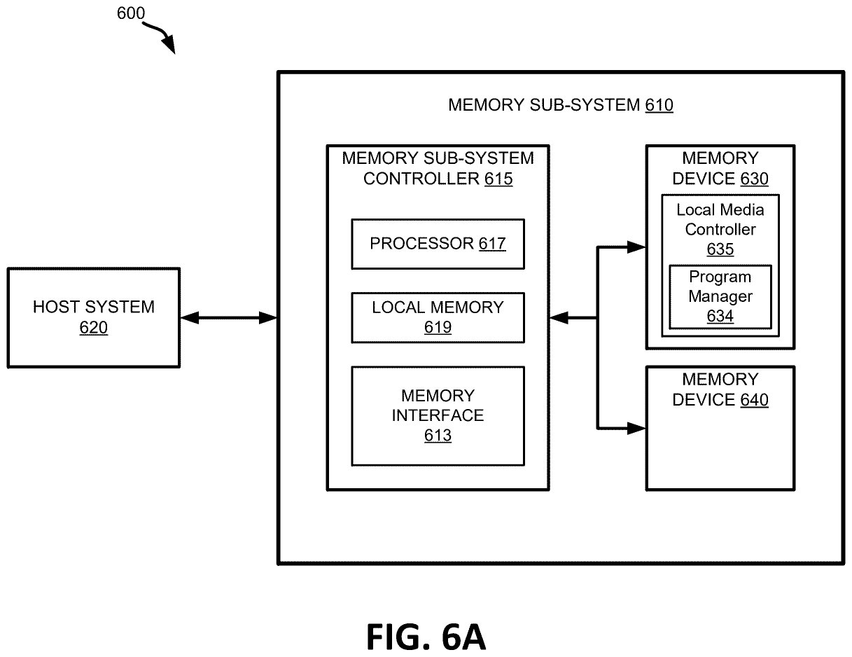

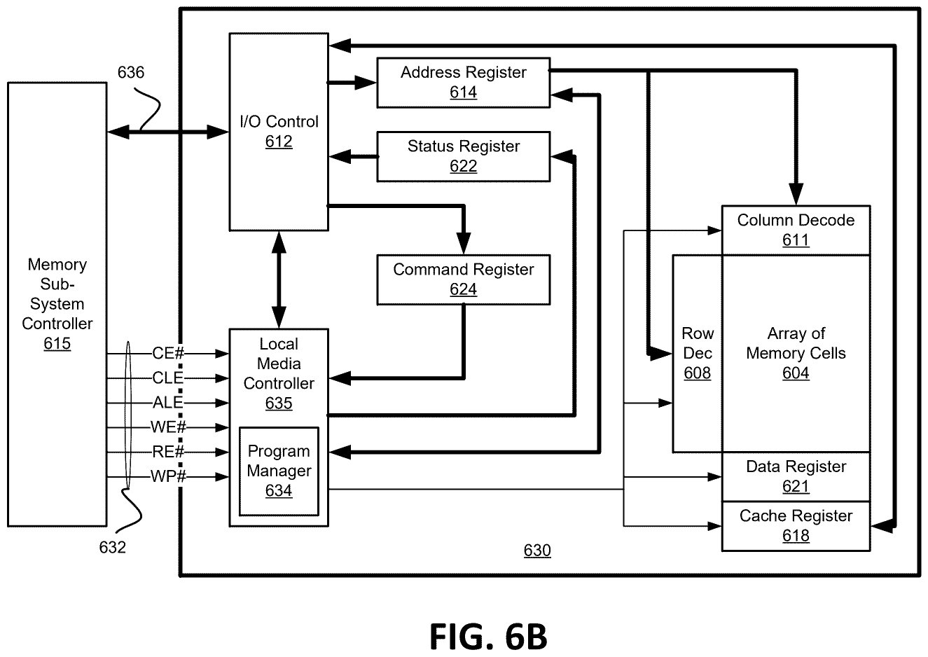

FIG. 6A illustrates an example computing system 600 that includes a memory sub-system 610 in accordance with some embodiments of the present disclosure. In some embodiments, one or more components of computing system 600 include insulating buffers at least partially surrounding an associated contact as described herein above. The memory sub-system 610 can include media, such as one or more volatile memory devices (e.g., memory device 640), one or more non-volatile memory devices (e.g., memory device 630), or a combination of such.

A memory sub-system 610 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 600 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 600 can include a host system 620 that is coupled to one or more memory sub-systems 610. In some embodiments, the host system 620 is coupled to multiple memory sub-systems 610 of different types. FIG. 6A illustrates one example of a host system 620 coupled to one memory sub-system 610. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 620 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 620 uses the memory sub-system 610, for example, to write data to the memory sub-system 610 and read data from the memory sub-system 610.

The host system 620 can be coupled to the memory sub-system 610 via a physical host interface. Examples of a physical host interface include a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 620 and the memory sub-system 610. The host system 620 can further utilize an NVM Express (NVMe) interface to access components (e.g., memory devices 630) when the memory sub-system 610 is coupled with the host system 620 by the physical host interface (e.g., PCIe bus). The physical host interface can provide an interface for passing control, address, data, and other signals between the memory sub-system 610 and the host system 620. FIG. 6A illustrates a memory sub-system 610 as an example. In general, the host system 620 can access multiple memory sub-systems via a same communication connection, multiple separate communication connections, and/or a combination of communication connections.

The memory devices 630, 640 can include any combination of the different types of non-volatile memory devices and/or volatile memory devices. The volatile memory devices (e.g., memory device 640) can be random access memory (RAM), such as dynamic random access memory (DRAM) and synchronous dynamic random access memory (SDRAM).

Some examples of non-volatile memory devices (e.g., memory device 630) include a negative- and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 630 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 630 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 630 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 630 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative- or (NOR) flash memory, or electrically erasable programmable read-only memory (EEPROM).

A memory sub-system controller 615 (or controller 615 for simplicity) can communicate with the memory devices 630 to perform operations such as reading data, writing data, or erasing data at the memory devices 630 and other such operations. The memory sub-system controller 615 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 615 can be a microcontroller, special purpose logic circuitry (e.g., a field programmable gate array (FPGA), an application specific integrated circuit (ASIC), etc.), or other suitable processor.

The memory sub-system controller 615 can include a processing device, which includes one or more processors (e.g., processor 617), configured to execute instructions stored in a local memory 619. In the illustrated example, the local memory 619 of the memory sub-system controller 615 includes an embedded memory configured to store instructions for performing various processes, operations, logic flows, and routines that control operation of the memory sub-system 610, including handling communications between the memory sub-system 610 and the host system 620.

In some embodiments, the local memory 619 can include memory registers storing memory pointers, fetched data, etc. The local memory 619 can also include read-only memory (ROM) for storing micro-code. While the example memory sub-system 610 in FIG. 6A has been illustrated as including the memory sub-system controller 615, in another embodiment of the present disclosure, a memory sub-system 610 does not include a memory sub-system controller 615, and can instead rely upon external control (e.g., provided by an external host, or by a processor or controller separate from the memory sub-system).

In general, the memory sub-system controller 615 can receive commands or operations from the host system 620 and can convert the commands or operations into instructions or appropriate commands to achieve the desired access to the memory devices 630. The memory sub-system controller 615 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 630. The memory sub-system controller 615 can further include host interface circuitry to communicate with the host system 620 via the physical host interface. The host interface circuitry can convert the commands received from the host system into command instructions to access the memory devices 630 as well as convert responses associated with the memory devices 630 into information for the host system 620.

The memory sub-system 610 can also include additional circuitry or components that are not illustrated. In some embodiments, the memory sub-system 610 can include a cache or buffer (e.g., DRAM) and address circuitry (e.g., a row decoder and a column decoder) that can receive an address from the memory sub-system controller 615 and decode the address to access the memory devices 630.

In some embodiments, the memory devices 630 include local media controllers 635 that operate in conjunction with memory sub-system controller 615 to execute operations on one or more memory cells of the memory devices 630. An external controller (e.g., memory sub-system controller 615) can externally manage the memory device 630 (e.g., perform media management operations on the memory device 630). In some embodiments, memory sub-system 610 is a managed memory device, which is a raw memory device 630 having control logic (e.g., local media controller 635) on the die and a controller (e.g., memory sub-system controller 615) for media management within the same memory device package. An example of a managed memory device is a managed NAND (MNAND) device.

The memory sub-system 610 includes a memory interface component 613 that can handle interactions of memory sub-system controller 615 with the memory devices of memory sub-system 610, such as memory device 630. For example, memory interface component 613 can receive data from memory device 630, such as data retrieved in response to a read operation or a write operation. In some examples, the memory sub-system controller 615 can include a processor 617 (processing device) configured to execute instructions stored in local memory 619 for performing the operations described herein.

In some embodiments, memory device 630 includes a program manager 634. In some embodiments, local media controller 635 includes at least a portion of program manager 634 and is configured to perform various memory functions. In some embodiments, the program manager 634 is part of the host system 610, an application, or an operating system. Further details with regards to the operations of program manager 634 are described below. In some embodiments, program manager 634 is implemented on memory device 630 using firmware, hardware components, or a combination of the above.

FIG. 6B is a simplified block diagram of a first apparatus, in the form of a memory device 630, in communication with a second apparatus, in the form of a memory sub-system controller 615 of a memory sub-system (e.g., memory sub-system 610 of FIG. 6A), according to an embodiment. In some embodiments, one or more components of memory device 630 include conductive lines manufactured according to a method described herein above. Some examples of electronic systems include personal computers, personal digital assistants (PDAs), digital cameras, digital media players, digital recorders, games, appliances, vehicles, wireless devices, mobile telephones and the like. The memory sub-system controller 615 (e.g., a controller external to the memory device 630), can be a memory controller or other external host device.

Memory device 630 includes an array of memory cells 604 logically arranged in rows and columns. Memory cells of a logical row are typically connected to the same access line (e.g., a wordline) while memory cells of a logical column are typically selectively connected to the same data line (e.g., a bit line). A single access line can be associated with more than one logical row of memory cells and a single data line can be associated with more than one logical column. Memory cells (not shown in FIG. 6B) of at least a portion of array of memory cells 604 are capable of being programmed to one of at least two target data states.

Row decode circuitry 608 and column decode circuitry 611 are provided to decode address signals. Address signals are received and decoded to access the array of memory cells 604. Memory device 630 also includes input/output (I/O) control circuitry 612 to manage input of commands, addresses and data to the memory device 630 as well as output of data and status information from the memory device 630. An address register 614 is in communication with I/O control circuitry 612 and row decode circuitry 608 and column decode circuitry 611 to latch the address signals prior to decoding. A command register 624 is in communication with I/O control circuitry 612 and local media controller 635 to latch incoming commands.

A controller (e.g., the local media controller 635 internal to the memory device 630) controls access to the array of memory cells 604 in response to the commands and generates status information for the external memory sub-system controller 615, i.e., the local media controller 635 is configured to perform access operations (e.g., read operations, programming operations and/or erase operations) on the array of memory cells 604. The local media controller 635 is in communication with row decode circuitry 608 and column decode circuitry 611 to control the row decode circuitry 608 and column decode circuitry 611 in response to the addresses. In at least one embodiment, local media controller 635 includes program manager 634, which can implement the bad block mapping operations with respect to memory device 630, as described herein.

The local media controller 635 is also in communication with a cache register 618. Cache register 618 latches data, either incoming or outgoing, as directed by the local media controller 635 to temporarily store data while the array of memory cells 604 is busy writing or reading, respectively, other data. During a programming operation (e.g., a write operation), data can be passed from the cache register 618 to the data register 621 for transfer to the array of memory cells 604; then new data can be latched in the cache register 618 from the I/O control circuitry 612. During a read operation, data can be passed from the cache register 618 to the I/O control circuitry 612 for output to the memory sub-system controller 615; then new data can be passed from the data register 621 to the cache register 618. The cache register 618 and/or the data register 621 can form (e.g., can form a portion of) a page buffer of the memory device 630. A page buffer can further include sensing devices (not shown in FIG. 6B) to sense a data state of a memory cell of the array of memory cells 604, e.g., by sensing a state of a data line connected to that memory cell. A status register 622 can be in communication with I/O control circuitry 612 and the local memory controller 635 to latch the status information for output to the memory sub-system controller 615.

Memory device 630 receives control signals at the memory sub-system controller 615 from the local media controller 635 over a control link 632. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 632 depending upon the nature of the memory device 630. In at least one embodiment, memory device 630 receives command signals (which represent commands), address signals (which represent addresses), and data signals (which represent data) from the memory sub-system controller 615 over a multiplexed input/output (I/O) bus 636 and outputs data to the memory sub-system controller 615 over I/O bus 636.

For example, the commands can be received over input/output (I/O) pins [7:0] of I/O bus 636 at I/O control circuitry 612 and can then be written into command register 624. The addresses can be received over input/output (I/O) pins [7:0] of I/O bus 636 at I/O control circuitry 612 and can then be written into address register 614. The data can be received over input/output (I/O) pins [7:0] for an 8-bit device or input/output (I/O) pins [15:0] for a 16-bit device at I/O control circuitry 612 and then can be written into cache register 618. The data can be subsequently written into data register 621 for programming the array of memory cells 604.

In at least one embodiment, cache register 618 can be omitted, and the data can be written directly into data register 621. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 630 by an external device (e.g., the memory sub-system controller 615), such as conductive pads or conductive bumps as are commonly used.

In some implementations, additional circuitry and signals can be provided, and that the memory device 630 of FIG. 6B has been simplified. It should be recognized that the functionality of the various block components described with reference to FIG. 6B cannot necessarily be segregated to distinct components or component portions of an integrated circuit device. For example, a single component or component portion of an integrated circuit device could be adapted to perform the functionality of more than one block component of FIG. 6B. Alternatively, one or more components or component portions of an integrated circuit device could be combined to perform the functionality of a single block component of FIG. 6B. Additionally, while specific I/O pins are described in accordance with popular conventions for receipt and output of the various signals, it is noted that other combinations or numbers of I/O pins (or other I/O node structures) can be used in the various embodiments.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A memory array, comprising:
a stack of layers comprising alternating layers of a dielectric material and a conductive material;
a plurality of supporting pillars extending through the stack of layers within a first region of at least one layer of the stack of layers;
a plurality of contacts extending through the stack of layers within a second region of the at least one layer of the stack of layers; and
a plurality of insulating buffers disposed at a transition region of the at least one layer of the stack of layers, the transition region located between the first region and the second region, wherein each of the plurality of insulating buffers at least partially surrounds an associated contact of the plurality of contacts.

2. The memory array of claim 1, wherein a first subset of the plurality of supporting pillars and a first subset of the plurality of contacts are associated with a first sub-block of the memory array, wherein a second subset of the plurality of supporting pillars and a second subset of the plurality of contacts are associated with a second sub-block of the memory array, and wherein at least one of the plurality of insulating buffers at least partially separates the first sub-block of the memory array from the second sub-block of the memory array.

3. The memory array of claim 2, wherein the plurality of contacts are arranged in at least a first row of contacts and a second row of contacts, wherein the first row of contacts is closer to the transition region than the second row of contacts, wherein each of the plurality of insulating buffers at least partially surrounds the associated contact at the first row of contacts.

4. The memory array of claim 1, wherein at least one of the plurality of insulating buffers has an oxbow-shaped cross-section.

5. The memory array of claim 1, wherein the plurality of insulating buffers comprise an electrically-insulating material.

6. The memory array of claim 5, wherein the electrically-insulating material comprises an oxide.

7. The memory array of claim 1, wherein the plurality of insulating buffers extend through at least one layer of the stack of layers, the at least one layer of the stack of layers corresponding to a top deck of the stack of layers.

8. An electronic device, comprising:
a plurality of supporting pillars extending through a tier stack within a first region of at least one layer of the tier stack;
a plurality of contacts extending through the tier stack within a second region of the at least one layer of the tier stack; and
a plurality of insulating buffers disposed at a transition region located between the first region and the second region, wherein each of the plurality of insulating buffers at least partially surrounds an associated contact of the plurality of contacts.

9. The electronic device of claim 8, wherein the electronic device is a memory array, wherein a first subset of the plurality of supporting pillars and a first subset of the plurality of contacts are associated with a first sub-block of the memory array, wherein a second subset of the plurality of supporting pillars and a second subset of the plurality of contacts are associated with a second sub-block of the memory array, and wherein at least one of the plurality of insulating buffers at least partially separates the first sub-block of the memory array from the second sub-block of the memory array.

10. The electronic device of claim 9, wherein the plurality of contacts are arranged in at least a first row of contacts and a second row of contacts, wherein the first row of contacts is closer to the transition region than the second row of contacts, wherein each of the plurality of insulating buffers at least partially surrounds the associated contact at the first row of contacts.

11. The electronic device of claim 8, wherein at least one of the plurality of insulating buffers has an oxbow-shaped cross-section.

12. The electronic device of claim 8, wherein the plurality of insulating buffers comprise an electrically-insulating material comprising an oxide.

13. The electronic device of claim 8, wherein the plurality of insulating buffers extend through at least one layer of the tier stack, the at least one layer of the tier stack corresponding to a top deck of the tier stack.

14. A method, comprising:
forming a stack of layers of an electronic circuit, the stack of layers comprising alternating layers of a dielectric material and conductive material;
forming a plurality of supporting pillars extending through the stack of layers within a first region of at least one layer of the stack of layers;
forming a plurality of contacts extending through the stack of layers within a second region of the at least one layer of the stack of layers;
etching at least a top layer of the stack of layers to form a plurality of voids disposed at a transition region of the at least one layer of the stack of layers, the transition region located between the first region and the second region, wherein each of the plurality of voids at least partially surrounds an associated contact of the plurality of contacts; and
filling the plurality of voids with an electrically-insulating material to form a plurality of insulating buffers at the transition region, wherein each of the plurality of insulating buffers at least partially surrounds an associated contact of the plurality of contacts.

15. The method of claim 14, further comprising:
etching at least the top layer of the stack of layers to form a slit separating a first subset of the plurality of supporting pillars and a first subset of the plurality of contacts from a second subset of the plurality of supporting pillars and a second subset of the plurality of contacts; and
filling the slit with the electrically-insulating material to form a partition separating the first subset of the plurality of supporting pillars and the first subset of the plurality of contacts from the second subset of the plurality of supporting pillars and the second subset of the plurality of contacts.

16. The method of claim 15, wherein etching at least the top layer of the stack of layers to form the slit is performed concurrent with etching at least the top layer of the stack to form the plurality of voids, and wherein filling the slit with the electrically-insulating material to form the partition is performed concurrent with filling the plurality of voids with the electrically-insulating material to form the plurality of insulating buffers at the transition region.

17. The method of claim 16, wherein at least one of the plurality of insulating buffers at least partially separates the first subset of the plurality of supporting pillars and the first subset of the plurality of contacts from the second subset of the plurality of supporting pillars and the second subset of the plurality of contacts.

18. The method of claim 16, wherein the electrically-insulating material comprises an oxide.

19. The method of claim 14, wherein at least one of the plurality of insulating buffers has an oxbow-shaped cross-section.

20. The method of claim 14, wherein the plurality of insulating buffers extend through at least one layer of the stack of layers, the at least one layer of the stack of layers corresponding to a top deck of the stack of layers.
